(19) United States
(12) Patent Application Publication
(10) Pub. No.: US 2004/0036481 A1
(43) Pub. Date: Feb. 26, 2004

(54) Load-pulled haptomer-assisted detection

(75) Inventor: Bentley N. Scott, Garland, TX (US)

Correspondence Address: Robert O. Groover III, Arter & Hadden, LLP, 1100 Huntington Bldg., 925 Euclid Ave., Cleveland, OH, 44115, US

(73) Assignee: PHASE DYNAMICS Inc.

(21) Appl. No.: 10/393,513

(22) Filed: Mar. 19, 2003

Related U.S. Application Data
(60) Provisional application No. 60/366,128, filed on Mar. 19, 2002.

(51) Int. Cl. G01R 27/04; G01R 27/32

(52) U.S. Cl. 324/639

(57) ABSTRACT

High-sensitivity methods and systems for measuring small or trace concentrations of molecules of interest. A haptomeric material is positioned in contact with a fluid medium, and preferably within the peak E-field-volume of an electromagnetic probe. The haptomeric material will bind with high selectivity to the desired target substance (antigen), and the bound haptomer-antigen combination changes the observed dielectric properties, as seen from the electromagnetic probe. A load-pulled oscillator is the preferred detector configuration, but alternatively other electrical configurations can be used.

### CROSS REFERENCE TO OTHER APPLICATION

This application claims priority from Ser. No. 60/366,128, filed Mar. 19, 2002, which is hereby incorporated by reference.

### BACKGROUND AND SUMMARY OF THE INVENTION

The present invention pertains to the real-time detection and measurement of a particular substance in a given sample and, in particular, to a load-pulled haptomer-assisted binding detection system and method.

### Background: Load-Pulled Oscillators

It is well known to electrical engineers generally (and particularly to microwave engineers) that the frequency of an RF oscillator can be “pulled” (i.e. shifted from the frequency of oscillation which would be seen if the oscillator were coupled to an ideal impedance-matched pure resistance), if the oscillator sees an impedance which is different from the ideal matched impedance. Thus, a varying load impedance may cause the oscillator frequency to shift. For example, an unbuffered RF oscillator is loaded by an electromagnetic propagation structure which is electromagnetically coupled, by proximity, to a material for which real-time monitoring is desired. The net complex impedance seen by the oscillator will vary as the characteristics of the material in the electromagnetic propagation structure varies. As this complex impedance changes, the oscillator frequency will vary. Thus, the frequency variation (which can easily be measured) can reflect changes in density (due to bonding changes, addition of additional molecular chains, etc.), ionic content, dielectric constant, or microwave loss characteristics of the medium under study. These changes will “pull” the resonant frequency of the oscillator system. Changes in the medium's magnetic permeability will also tend to cause a frequency change, since the propagation of the RF energy is an electromagnetic process which is coupled to both electric fields and magnetic fields within the transmission line.

Load-pulled oscillators, which make use of this effect, are an important technique for RF monitoring. A free-running oscillator, typically at VHF or higher frequencies, is electromagnetically coupled to some environment which is desired to be characterized. (For example, an unknown oil/water/gas composition can be flowed through a coaxial probe section.) Since the oscillator is not isolated from the environment being measured, changes in that environment will pull the frequency of oscillation. By monitoring shifts in the frequency of oscillation, changes in the environment being monitored can be seen with great precision. (For example, in compositional monitoring of wellhead flows of oil/gas/water mixtures, the environment being monitored is a medium having a variable composition, and changes in the composition are seen as shifts in the oscillation frequency for a given tuning voltage.)

The load pulled oscillator requires a topology which will support oscillations throughout a change in the load impedance from the capacitive to inductive loading. Typically such an oscillator must cover octave or more bandwidths and remain capable of oscillating into any load impedance or phase within its range.

Extensive work by the present inventor and others has shown that load-pulled oscillators have important capabilities for measurement and characterization. See U.S. Pat. Nos. 4,862,060, 4,996,490, 5,025,222, 5,748,002, and 6,166,551, and PCT applications WO 91/00997 and WO 91/08469, all of which are hereby incorporated by reference. This “load-pulled” technology provides an economical measurement technique which has improved sensitivities by 100× to 1000× over any prior instrumentation for measurement of microwave phase.

### Background: Properties of a Dielectric in a Transmission Line

To help explain the use of the load-pull effect in the disclosed innovations, the electromagnetics of a dielectric-loaded transmission line will first be reviewed. If a transmission line is (electrically) loaded with a dielectric material, changes in the composition of the dielectric material may cause electrical changes in the properties of the line. In particular, the impedance of the line, and the phase velocity of wave propagation in the line, may change.

This can be most readily illustrated by first considering propagation of a plane wave in free space. The propagation of a time-harmonic plane wave (of frequency f) in a uniform material will satisfy the reduced wave equation

(∇²+k²)E=(∇²+k²)H=0,

where

E is the electric field (vector),

H is the magnetic field (vector), and

∇² represents the sum of second partial derivatives along the three spatial axes.

This equation can be solved to define the electric field vector E, at any point r and time t, as

E(r,t)=E₀exp[i(k·r−ω)],

where

k is a wave propagation vector which points in the direction of propagation and has a magnitude equal to the wave number k, and

ω=Angular Frequency=2πf.

In a vacuum, the wave number k has a value “k₀” which is

$${k}_{0} = ω / c \\ = {ω ( {μ}_{0} {ε}_{0} )}^{\frac{1}{2}} ,$$

where

μ₀=Magnetic Permeability of vacuum (4π=10⁻⁷ Henrys per meter),

∈₀=Electric Permittivity of vacuum ((1/36π)×10⁻⁹ Farads per meter), and

c=Speed of light=(_{μ0∈0})^{-1/2}=2.998×10⁸ meters/second.

However, in a dielectric material, the wave number k is not equal to k₀; instead

where

$$k = ω / ( {c ( {μ}_{r} {ε}_{r} )}^{\frac{1}{2}} ) \\ = {ω ( {μ}_{0} {μ}_{r} {ε}_{0} {ε}_{r} )}^{\frac{1}{2}} ,$$

μᵣ=Relative Permeability of the material (normalized to the permeability ∈₀ of a vacuum), and

∈ᵣ=Relative Permittivity of the material (normalized to the permittivity ∈₀ of a vacuum).

Thus, if the relative permeability μᵣ and/or the relative permittivity ∈ᵣ vary, the wave number k and the wave propagation vector k will also vary, and this variation will typically affect the load pulled oscillator frequency.

### Background: Frequency Hopping in a Load-Pulled Oscillator

In a typical free-running oscillator, the oscillator frequency is defined by a resonant feedback circuit (the “tank” circuit), and can also be pulled slightly by a reactive load, as noted above. Thus, such an oscillator can be broadly tuned by including a varactor in the tank circuit.

As the oscillator's frequency is thus shifted, the phase difference between the energy incident on and reflected from the load element (which is preferably a shorted transmission line segment) will change. This phase difference will be equal to an exact multiple of 180° at any frequency where the electrical length of the transmission line segment is an exact multiple of λ/4.

As the oscillator frequency passes through such a frequency (i.e. one where the transmission line segment's electrical length is equal to a multiple of λ/4), the load's net impedance will change from inductive to capacitive (or vice versa). As this occurs, the frequency of the oscillator may change abruptly rather than smoothly. This jump in frequency will be referred to as a frequency “hop”.

For a transmission line of length l which contains a dielectric material of relative dielectric constant ∈ᵣ, the frequency at which one full wavelength (1λ) exists in the transmission line is equal to c (the speed of light in vacuum, which is 2.995×10⁸ meters/second) divided by the length of the line in meters and by the square root of the relative dielectric constant of the material:

Frequency _{1 λ}=c/(l∈ᵣ^{1/2}).

For example, for a one-foot-long line filled with a material having ∈ᵣ =1, l=12 inches (=0.3048 meters), and

Frequency_{1λ},=(2.995×10⁸)/(0.3048×1.0)˜980 MHz.

However, since one wavelength actually contains two excursions from inductive to capacitive reactive impedances, only one-half wavelength is required to see one frequency hop of the load pulled oscillator. If the transmission line is terminated into a short or an open, the resulting effective length is increased to twice the actual length, since a standing wave is generated (due to the energy incident at the short or open being reflected back to the input of the transmission line). In essence, the energy travels down the line, gets reflected, and travels back to the input. With this taken into account, the first frequency with a wavelength long enough to cause a frequency “hop” of the oscillator is one fourth the length calculated above, or 245 MHz.

Multiples of this first quarter-wavelength frequency will also cause the impedance seen at the input to the transmission line to go from inductive to capacitive reactance. The longer the transmission line, the greater the number of phase transitions that will occur. Longer line length also multiplies the phase changes that are brought about by a change in the dielectric constant. For every one-quarter wavelength change in the effective (electrical) length of the line, the complex impedance seen at the oscillator changes by 180°.

For example, suppose that a given oscillator, coupled into a low loss load with an electrical length of one-quarter wavelength (λ/4), provides 50 MHz of load pulling frequency change (total excursion through all phases). If the monitored material changes enough to produce a change of only one degree of phase in the electrical length of the load, the oscillator frequency will change by 138.9 kHz. This represents an absolute resolution of 7.2×10⁻⁶ degrees of phase change for each Hertz of sensitivity. For every additional quarter wavelength of line length, this sensitivity to phase is multiplied by 1.5. This is due to the change in phase being an additive function of every additional quarter wave in the measurement section.

In a typical tuning frequency versus voltage plot for a VCO loaded into a shorted transmission line, the height of the “hop” can be measured by holding the VCO tuning voltage constant, while a transmission line terminated into a short is varied in length to cause a full rotation of the impedance vector seen at the VCO's input port. The resulting data of frequency versus length of the transmission line will show a jump in frequency (a delta frequency from the bottom of the “hop” to the top of the “hop”) which coincides with the delta frequency of the “hop” seen when the VCO was swept using the tuning voltage. ¹Such variable transmission lines are commonly used in the microwave industry, and are referred to as “line stretchers.”

Thus, if the VCO is swept across a frequency band and the number of frequency “hops” was counted, the number of “hops” reveals the number of wavelengths in the transmission line.

This provides a means for determination of the range of dielectric constant change in a medium even when it rotates the phase vector multiple times (and therefore, the oscillator frequency returns to the same value multiple times). If the dielectric constant of the material in the transmission line is increased, then the above equations show that the frequency of the first full wavelength is decreased by the square root of the dielectric constant. Additionally, this means that the number of wavelengths at a fixed frequency increases with increasing dielectric constant. These facts imply that the VCO tuning curve will see more “hops” as the dielectric constant is increased due to the increasing fraction or whole wavelengths encountered.

Ideally, the oscillator will not cease oscillations (or break into multiple frequency oscillation or spectral breakup) into any load regardless of the load characteristics. However, this is not a strictly necessary condition for use of the disclosed method and system innovations.

### Background: Load-Switching in Load-Pulled Systems

U.S. Pat. No. 5,748,002 (of common ownership and overlapping inventorship with the present application, and hereby incorporated by reference) discloses (among many other teachings) a probe, for load-pulled oscillator measurements, with the capability for switching between two different load segments. As stated in that patent: “FIG. 4E shows a planar probe 18 with TWO transmission lines 21D (only one of them overlain by an added selective absorption layer), and an RF switch 22′ to select which of the two transmission lines 21D will be active. There are many ways to use this capability. For example, one of the two lines can be an uncovered metal trace and the other can be covered with a material which selectively absorbs (or reacts with) a particular chemical. . . . This can also be used to provide spatially-resolved differential measurement for detection of spatially-varying characteristics (e.g. material zone boundaries in a distillation or chromatographic column).”

### Background: Other Approaches to Electrical Characterization

Various types of apparatus have been proposed for measuring the concentration of one substance in another, particularly the concentration of a liquid or flowable substance in another liquid or flowable substance. These approaches have very different electrical design characteristics from load-pulled techniques, and substantially different performance capabilities.

Various devices which utilize the broad concept of determining composition of matter by measuring changes in a microwave signal are disclosed in U.S. Pat. No. 3,498,112 to Howard; U.S. Pat. No. 3,693,079 to Walker; U.S. Pat. No. 4,206,399 to Fitzky et al.; U.S. Pat. No. 4,311,957 to Hewitt et al.; 4,361,801 to Meyer et al.; U.S. Pat. No. 4,240,028 to Davis Jr.; U.S. Pat. No. 4,352,288 to Paap et al.; U.S. Pat. No. 4,499,418 to Helms et al.; and U.S. Pat. No. 4,367,440 and U.S. Pat. No. 4,429,273, both to Mazzagatti; all of which are hereby incorporated by reference.

Although various systems utilizing microwave transmissivity or signal alteration characteristics have been proposed in the prior art, certain considerations in utilizing microwave energy to detect the presence of the concentration of one medium in another have not been met by prior art apparatus. In particular, it is desirable in certain instances to be able to accurately measure, on a continuous basis, the concentration or change in concentration of one fluid in another and particularly where the concentration of one fluid is a very low percentage of the total fluid flow rate or fluid mixture quantity. It is also desirable that the signal change caused by the presence of one substance or medium in another be easily measured and be relatively error free, again, particularly in instances where measurements of low concentrations of one substance such as a fluid in another substance such as another fluid are being taken. Moreover, it is important to be able to transmit the microwave signal through a true cross section of the composition being sampled or measured to enhance the accuracy of the measurement.

Typical systems for capacitive based measurement have a capacitive element, used for parameter determination, as part of the resonant feedback loop around an active device. This method works well with very low loss systems, but oscillation ceases with even slightly lossy measurements. As the frequency is increased into the microwave region, it becomes difficult to configure the resonant feedback loop due to the increase in loss versus frequency and the wavelength becoming comparable to the path length. In this case the frequency is changed directly by the resonance change in the feedback loop which includes the element that consists of the sample to be measured. This frequency change is limited to the characteristics and loss of the feedback path and can only be changed over a narrow frequency range with out cessation of oscillations. This limits the measurement technique to small samples of very low loss.

At higher frequencies (above approximately 100 MHz), the capacitive measurement technique fails to work, due to line lengths and stray capacitances. At such frequencies resonant cavity techniques have been employed. (For example, a sample is placed in a resonant cavity to measure the loss and frequency shift with a external microwave frequency source that can be swept across the resonance with and without the sample in the cavity.) This method uses a highly isolated microwave frequency source which is forced by the user (rather than being pulled by the changing resonance) to change its frequency. This technique too meets substantial difficulties. For example, the use of multiple interfaces without a microwave impedance match at each interface causes extraneous reflections, which tend to hide the desired measurement data. This technique too gives errors with very lossy material, but in this case it is due to the very rounded nature of the resonance curve (which is due to the low Q of the loaded cavity). This rounded curve makes it difficult to determine both the center frequency and the 3 dB rolloff frequency closely enough to be accurate in the measurement.

Another technique which is used encompasses the use of a very sharp rise time pulse to obtain time domain data, from which frequency domain values are then derived through transformation techniques.

In U.S. Pat. No. 4,396,062 to Iskander, entitled Apparatus and Method for Time-Domain Tracking of High-speed Chemical Reactions, the technique used is time domain reflectometry (TDR). This contains a feedback system comprising a measurement of the complex permittivity by TDR means which then forces a change in frequency of the source which is heating the formation to optimize this operation. Additionally it covers the measurement of the complex permittivity by TDR methods.

U.S. Pat. No. 3,965,416 to Friedman appears to teach the use of pulse drivers to excite unstable, bi-stable, or relaxation circuits, and thereby propagate a pulsed signal down a transmission line which contains the medium of interest. The pulse delay is indicative of the dielectric constant of the medium. As in all cases, these are either square wave pulses about zero or positive or negative pulses. The circuit is a pulse delay oscillator where the frequency determining element is a shorted transmission line. The frequency generated is promoted and sustained by the return reflection of each pulse. The circuit will not sustain itself into a load that is lossy, since the re-triggering will not occur without a return signal of sufficient magnitude. In addition, the circuit requires a load which is a DC short in order to complete the DC return path that is required for re-triggering the tunnel diodes.

The frequencies of operation of any pulse system can be represented as a Fourier Series with a maximum frequency which is inversely dependent upon the rise time of the pulse. Therefore, the system covered in the Friedman patent is dependent upon the summation of the frequency response across a wide bandwidth. This causes increased distortion of the return pulse and prevents a selective identification of the dielectric constant versus frequency. This also forces a design of the transmission system to meet stringent criteria to prevent additional reflections across a large bandwidth.

The low frequency limit of the TDR technique is determined by the time window which is a function of the length of the transmission line. The upper extreme is determined by the frequency content of the applied pulse. In the case of this pulse delay line oscillator, the upper frequency is determined to a greater extent by the quality of impedance match (the lack of extra reflections) from the circuit through to the substance under study. These extra reflections would more easily upset the re-triggering at higher frequencies.

In one case (FIG. 1 of Friedman) the return reflection initiates a new pulse from the tunnel diode and therefore sets up a frequency (pulse repetition rate) as new pulses continue to be propagated. This is in essence a monostable multivibrator with the return reflection being the trigger. The problem implied, but not completely covered with this approach, is that due to the delay in pulses, the pulse train can overlap and cause multiple triggers to occur. These are caused by the re-reflections of the original parent pulse. An additional problem is with very lossy dielectrics, which will not provide enough feedback signal to initiate the next pulse. If the dielectric medium is of high enough dielectric constant to contain more than one wavelength, or if the dielectric constant of the samples vary greatly, multiple return reflections will alter the behavior of the circuit to render it useless due to the interfering train of return and parent pulses.

FIG. 3 of Friedman shows a bistable multivibrator which senses the return pulse by sampling and feeding back enough phase shifted voltage to re-set the tunnel diodes. Since this device is also dependent upon the return to trigger or re-trigger the parent pulse, it suffers problems with lossy dielectrics and high dielectric constant mediums.

To overcome these problems, the relaxation oscillator of FIG. 4 of Friedman was proposed that contains a RC (resistor/capacitor timing) network which will maintain the generation of pulse trains using resistor 76 and capacitor 78 with the dielectric filled transmission line affecting the regeneration of the pulses as the reflected parent pulse voltage is returned. Since the RC time constant is defining the basic repetition rate, some improvement is obtained in reducing second order effects. The transmission line is still an integral part of the overall relaxation oscillator and lossy dielectrics may cause irregular circuit response. The proposed inverting amplifier as the pulse generator will not function at above approximately 1 MHz in frequency due to the characteristics of such inverting amplifiers. The tunnel diode can pulse up to a 100 MHz rate.

By contrast, the innovative system embodiments disclosed in the present application and its parents differ from the known prior art in using a microwave frequency generated by a free running sine wave oscillator. The preferred oscillator has the versatile capability to work into a wide variety of transmission lines or other load impedance without generation of spurious data or cessation of oscillations. It will continue to oscillate with very lossy dielectrics. It is not a relaxation oscillator or a multivibrator. The frequency of the un-isolated oscillator is dependent upon the net complex impedance of the transmission line and will work into an open circuit as well as a short circuit. The net complex impedance at the frequency of operation of the oscillator looking at the transmission line containing the medium of interest results in stable oscillations through pulling of the unisolated oscillator. Only one frequency at any one time is involved in the disclosed system proposed (not counting harmonics which are at least 10 dB down from the fundamental). This provides for well defined information and eases the transmission design criteria. This also provides for evaluation of the dielectric constant versus frequency which can improve resolution of constituents or ionic activity.

Another important difference from prior art is the separation of the load of interest from the resonant circuit proper. The configuration used isolates the two through the transistor. It is the non-linear behavior of the transistor that provides the changes in frequency as the load is changed. The loop gain of an oscillator must be unity with 180° phase shift. The initial gain of the transistor must be greater before oscillations begin in order for the oscillator to be self starting. This extra gain is reduced to unity by the saturation of the active device upon establishment of the oscillatory frequency. Saturating a device changes the gain (and accordingly the phase since it is non-linear) to maintain oscillations as the load changes. This will continue as the load changes as long as the transistor has appropriate phase and available gain to satisfy oscillations.

### Background: Antibody Structure and Antigen Binding

Immunoglobulins are the major secretory product of B cells and the major component of the humoral immunity system. Their synthesis is initiated by exposure of the organism to a foreign antigen which, after cellular processing, stimulates individual B cells which have receptors that recognize an epitope on the antigen.

The basic structural unit of all immunoglobulins is a symmetric four-chain heterodimer made of two identical heavy chains and two identical light chains which form the characteristic Y-shape. Each light chain binds a heavy chain with one or more disulfide bonds. The two heavy chains are bound with one or more disulfide bonds in the “hinge” region. All of these disulfide bonds contribute to the chemical stability of immunoglobulin molecules.

The most unique features of antibody structure are probably antigen recognition and binding which occurs at the ends of the “arms” of the Y structure. The antigen-antibody bond occurs through multiple noncovalent bonds including electrostatic, hydrogen, hydrophobic, and Van der Waals. Long-range forces such as electrostatic and hydrogen bonds are important in the rate of formation of antigen-antibody complexes at the points of contact. The short-range forces contribute significantly to bond strength by reducing the rate of complex dissociation.

The antigen binding is formed from the amino-terminal ends of the light and heavy chains. The two chains are folded to form globular variable domains similar to the folded domains of the constant regions. In the three-dimensional structure, hypervariable regions are brought close together to form looped segments called complementarity defining regions (CDRs).

The globular variable domains form a cleft or trough into which the epitope fits and binds with high affinity. As the cleft may be larger than the original epitope, it is clear that any antibody can conceivably bind other epitopes, especially those with similar structure, as long as the charged residues in either the antigen or the antibody in the binding site are compatible, i.e. no electrostatic repulsion.

### Background: Binding Theory of Immunoassays

The most widely used mathematical approach to the quantitative description of the multiple equilibria that occurs when an antibody binds reversibly to an antigen is the Scatchard model. The Scatchard model focuses on the individual binding sites of the antibody and applies the law of mass action for each site, s, defining the association constant K and assuming independent and noninteracting binding sites.

Thus, if we write the basic association reaction as

s+L⇄sL

we can write the association constant K as

$$K = \frac{B}{F ( N - B )}$$

where B and F represent the concentrations of the bound and free antigen respectively, and N is the total concentration of the binding sites. N is given by the product of the total binder concentration times the number of binding sites per binder molecule. N−B represents the concentration of free binding sites on the antibody.

The mass conservation of the antigen requires that

T=B+F

where T is the total antigen concentration. Solving for B/F gives:

$$\frac{B}{F} = K ( N - B ) .$$

The plot of B/F vs B for various antigen concentrations and a constant binder concentration is a straight line with a slope of −K. The x-axis intercept corresponds to an infinitely high antigen concentration and gives the total concentration N of binding sites.

### Load-Pulled Haptomer-Assisted Detection

The present application discloses high-sensitivity methods for measuring small or trace concentrations of molecules of interest. A haptomeric material is positioned in contact with a fluid medium, and preferably within the peak E-field-volume of an electromagnetic probe. The haptomeric material will bind with high selectivity to the desired target substance (antigen), and the bound haptomer-antigen combination changes the observed dielectric properties, as seen from the electromagnetic probe. A load-pulled oscillator is the preferred detector configuration, but alternatively other electrical configurations can be used.

Biological reactions frequently require that two molecules or more form a complex prior to the completion of the reaction. For this reason, it is of considerable fundamental, as well as practical, interest to be able to detect such interactions. However, reactions involving proteins often do not result in physical or chemical changes that can be conveniently monitored. In order to study such interactions, it is often necessary to label the interacting species with radiochemical or fluorescent tag. This labeling process is time-consuming and can interfere with the binding process itself.

The present invention is a useful tool for studying such interactions. It is based on the fact that if the surface of a molecule is modified by binding, then the physical properties, particularly the absorption of ultrasonic energy through mechanisms such as resonance relaxation, of the molecule will change. This change, which can be measured very accurately, can then be used to detect both the extent and rate of binding.

The present application utilizes a suitable dielectric material, such as ceramic or plastic, on which an antibody is coated. This dielectric material would be a part of a coaxial, waveguide or RF structure such that it forms an appropriate sensor.

A load-pull oscillator may be used as the sensing method. Downconversion is performed by directly beating a stable reference oscillation in a mixer to obtain an intermediate frequency which can be monitored in real-time to detect the attachment of an antigen onto the antibody.

In an alternative class of embodiments, this can be accomplished while hitting the structure with an ultrasonic frequency or sweeping this frequency while monitoring it with the RF/Microwave system. The area and length of measurement would be proportional to the wavelength and the frequency response of the antigen and its interaction with the antibody.

In the waveguide, the frequency operation will be high enough that the size of the antigen under study approaches a fractional wavelength. This coupled with selective frequency regions where the absorption may be maximum or where the relaxation frequency will provide a changing response with the attachment of the antigen can be selected.

Therefore, in contrast to conventional methods of assay, the present invention detects the association and dissociation of mobile reactants to an immobilized receptor on the surface of the sensor. The present invention is useful due to its ability to measure changes in a physical quantity, thereby, eliminating the need for exogenous labeling of the biological species involved. Other advantages of the present invention include real-time formation on the course of binding, the use of relatively small sample volumes, and the ability to measure binding from crude sample preparations.

### BRIEF DESCRIPTION OF THE DRAWING

The disclosed inventions will be described with reference to the accompanying drawings, which show important sample embodiments of the invention and which are incorporated in the specification hereof by reference, wherein:

FIG. 1 schematically shows the configuration of a complete system for implementing a first sample embodiment of the disclosed invention.

FIG. 2 shows a first sample configuration for differential detection, using one electromagnetic interface which is haptomer-loaded and another which is not.

FIG. 3 shows another sample configuration for differential detection, using one electromagnetic interface which is in proximity to a haptomeric material (haptomer-loaded binder), and another which is in proximity to a different binder material.

FIG. 4 schematically shows a configuration for implementing the disclosed invention which includes multiple electromagnetic interfaces.

FIG. 5 schematically shows a configuration for implementing the disclosed invention which includes the use of valves to control the flow of the sample.

FIG. 6 shows a flowchart of a process according to a sample embodiment.

FIGS. 7A, 7B and 7C show embodiments described in the parent application.

### DETAILED DESCRIPTION OF THE PREFERRED EMBODIMENTS

The numerous innovative teachings of the present application will be described with particular reference to the presently preferred embodiment (by way of example, and not of limitation).

### First Sample Embodiment

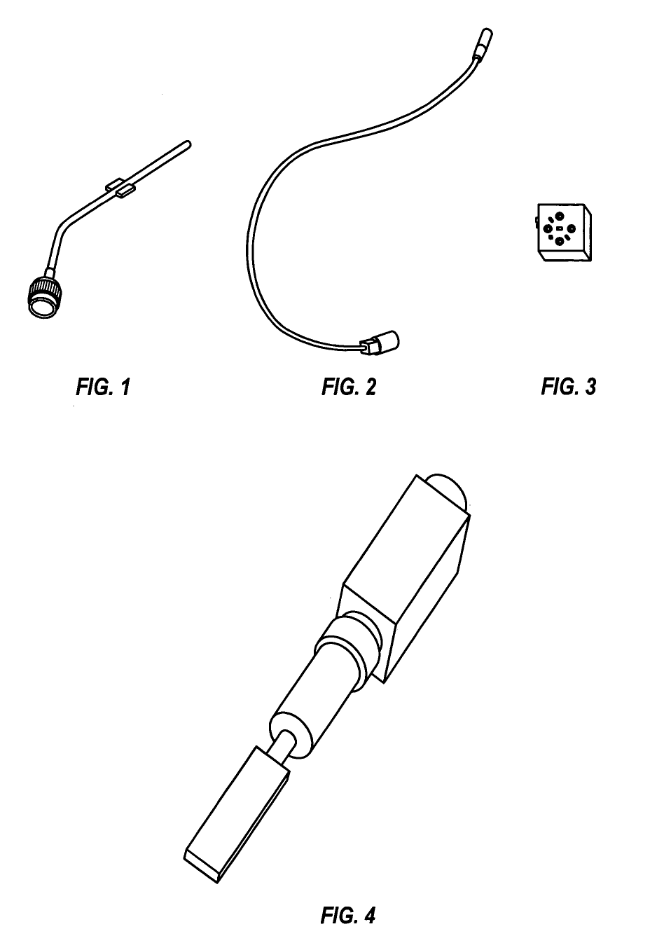

FIG. 1 schematically shows the configuration 100 of a complete system for implementing the disclosed invention. The sample 140 under measurement interacts with the binding material 120 on the surface of the electromagnetic interface 110. The binding material 120 contains haptomers specific to the antigen of interest. Electromagnetic interface 110 is connected to an RF energy source. The interaction of the haptomers in the binding material with the antigens in the sample produces a shift in the frequency of operation of the load pull oscillator 130. The measurement of the shift in frequency can be used to determine the presence and amount of a particular antigen in a given sample.

In this embodiment, electromagnetic interface 110 is gold on ceramic. The surface of electromagnetic interface 110 is coated with a Sepharose media. The surface of the Sepharose media would then be treated with cyanogen bromide to allow haptomers specific to the antigen of interest to bind to the surface of the Sepharose media. The Sepharose media together with the haptomers on its surface comprises binding material 120. Binding material 120 would then be held in place on electromagnetic interface 110 by using two glass frits with a pore diameter large enough to allow the antigen of interest in sample flow 140 to pass through and bind to the haptomers on the surface of binding material 120.

Sample flow 140 under measurement interacts with binding material 120. Since electromagnetic interface 110 is connected to load pull oscillator 130, the interaction of the haptomers in the binding material with the antigens in sample flow 140 produces a shift in the frequency of operation of the load pull oscillator 130.

The frequency of operation can be anything between 100 MHz and 100 GHz thereby allowing both the optimization of the absorption by energy or determination of the relaxation phenomena associated with the particular antigen of interest.

The area and length of measurement would be proportional to the wavelength and the frequency response of the antigen and its interaction with the antibody.

A further alternative is to set the operating frequency in a region where the absorption may be maximum or where the relaxation frequency will provide a changing response with the attachment of the antigen can be selected. The measurement of the shift in frequency can be used to determine the presence and amount of a particular antigen in a given sample.

The frequency of operation is preferably set high enough to concentrate the volume of maximal E-field within the haptomeric material.

### Sample Embodiment with Differential Sensing

FIG. 2 shows a first sample configuration for differential detection, using one electromagnetic interface which is haptomer-loaded and another which is not. This embodiment includes a second electromagnetic interface 210. The second electromagnetic interface 210 is connected either to a second load-pulled oscillator 220, or alternatively can be switched in to a single load-pulled oscillator.

### Sample Embodiment with Inert-Binder-Balanced Differential Sensing

FIG. 3 shows another sample configuration for differential detection, using one electromagnetic interface which is in proximity to a haptomeric material (haptomer-loaded binder), and another which is in proximity to a different binder material. This embodiment includes a second electromagnetic interface 210. In this embodiment, the second electromagnetic interface 210 contains a binding material that does not contain haptomers specific to the antigen of interest.

### Sample Embodiments with Differential Sensing

FIG. 4 schematically shows another differential sensing configuration using multiple multiple electromagnetic interfaces. This embodiment depicts multiple electromagnetic interfaces 110′ and 110″. The electromagnetic interfaces 110′ and 110″ have binding material 120′ and 120″ respectively on their surfaces. The binding material on the surface of the interfaces contain haptomers that are specific to the antigen of interest. Electromagnetic interfaces 110′ and 110″ are connected to load pull oscillators 130′ and 130″ respectively.

### Sample Embodiment with Selectable Flow Inputs

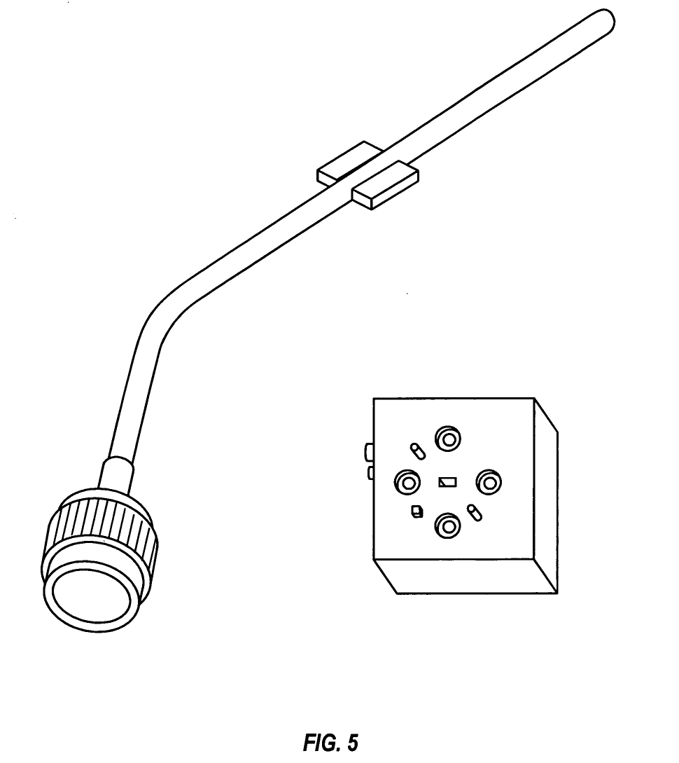

FIG. 5 schematically shows a configuration for implementing the disclosed invention which includes the use of valves V1 and V2 to control the flow of the sample stream. By switching flows, the probe can be exposed to a sidestream of the process flow, or to one or more calibration flows.

### Sample Process Sequence

FIG. 6 shows a flowchart of a process according to a sample embodiment, using the physical configuration of FIG. 5.

In step 610 valve V1 is opened, to pass a preconditioning flow over the probe surface. This preconditioner is preferably deionized water, buffered to a known pH (e.g. 6.8). Optionally, to accelerate depopulation of the antigen-binding sites, the preconditioning flow can be given a mild oxidizing or reducing chemistry, or loaded with a salt concentration, or given a more acidic or basic pH, within limits which will not degrade the haptomer-binder combination.

In a contemplated class of alternative embodiments, an eluting flow can be used first to clear antigen-binding sites, and the preconditioning flow can be matched to the approximate pH etc. of the sample flow.

In optional step 620 the oscillator is allowed to stabilize while the preconditioning flow is present. (Note that the flow rate of the preconditioning flow does not have to match that of the sample stream, although this is preferable.)

A baseline measurement is preferably recorded before the probe is exposed to the material stream to be characterized (step 630).

Valve V1 is now turned off, and valve V2 opened, to apply a sidestream of the material being measured to the probe (step 640). A time-series of measurements from the load-pulled oscillator are now recorded (step 650). Preferably the time resolution is comparable to the dwell time of fluid flow over the probe surface, but of course faster or slower sample rates can be used if desired.

### Additional Embodiments

FIGS. 7A, 7B and 7C show embodiments described in the parent application. FIG. 7A is a picture of hardware used for implementing the disclosed invention. Pictured are microstrip substrates 710, a waveguide 720, and coaxial lines 730.

FIG. 7B is a picture of hardware used for implementing the disclosed invention. Pictured are a coaxial line 735 cut in half to receive a sample and a waveguide slot 725 to receive a sample.

FIG. 7C is an enlarged picture of the hardware pictured in FIG. 7B.

### Definitions

Following are short definitions of the usual meanings of some of the technical terms which are used in the present application. (However, those of ordinary skill will recognize whether the context requires a different meaning.) Additional definitions can be found in the standard technical dictionaries and journals.

Haptomer: the commonest is an antibody, but single-chain antibodies, sulfide-stabilized antibodies, immunoconjugates, or enzymes can alternatively be substituted. In immunoconjugates the selective-binding portion is referred to as a “haptomer, ” and hence that term is used broadly in the present application for antibodies and analogous compounds.

Antigen: the complement of an antibody (or other haptomer).

Probe: the circuit element which is connected to a load-pulled oscillator (or other element for sensing dielectric laoding).

This circuit element can be a transmission line or can be a “patch probe.”

Binder: Sepharose is used, in the preferred embodiment, to provide antibody attachment sites, but of course a wide variety of alternatives can be used instead.

According to a disclosed class of innovative embodiments, there is provided: A measurement system comprising: an electromagnetic interface to a fluid medium; a coating of a binding material on said electromagnetic interface, said binding material containing haptomers which selectively bind to a particular antigen; and an RF electronics stage which is connected to provide RF energy to said electromagnetic interface and to be pulled by changing dielectric characteristics as haptomers in said binding material bind said antigen from said fluid medium.

According to another disclosed class of innovative embodiments, there is provided: A measurement system comprising: a first electromagnetic interface to a fluid medium; a coating of a binding material on said first electromagnetic interface, said binding material containing haptomers which selectively bind to a particular antigen; a second electromagnetic interface to the fluid medium; and an RF electronics stage which is connected to provide RF energy to said first and/or second electromagnetic interface and to be pulled by changing dielectric characteristics as haptomers in said binding material bind said antigen from said fluid medium.

According to another disclosed class of innovative embodiments, there is provided: A characterization method, comprising the actions of: providing RF energy to a circuit element which is electromagnetically loaded by a haptomeric material which is in contact with a fluid medium; and monitoring time-resolved reactive behavior of said circuit element, to thereby derive information about the presence, in said fluid medium, of antigens which bind selectively to said haptomeric material.

According to another disclosed class of innovative embodiments, there is provided: A characterization method, comprising the steps of: exposing a haptomeric material to a fluid medium; and monitoring changes in the dielectric properties of said haptomeric material, to thereby derive a measurement of the concentration, in said fluid medium, of antigens which bind selectively to said haptomeric material.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given.

In the preferred embodiment the binding medium is itself an ion-exchange resin, but of course other binding media can be used. It is preferred that the binding medium be sufficiently porous to permit fairly rapid equilibration of solute concentration between the fluid stream and the binding sites which are sensed by the probe, but this too can be varied.

While use of load-pulled technology is preferred, it should be noted that the disclosed probe innovations can also be used with other RF circuit configurations to detect changes in dielectric properties of the medium.

The following background publications provide additional detail regarding possible implementations of the disclosed embodiments, and of modifications and variations thereof, and the predictable results of such modifications: Brian Law, Immunoassay: A Practical Guide (1996); Immunoassays: Essential Data (ed. R. Edwards 1996); Reviews on Immunoassay Technology (ed. S. B. Pal, 1988-); Immunoassays: A Practical Approach (ed. J. Gosling, 2000); Antibody Usage in the Lab (Springer Lab Manual) (ed. L.Caponi and P. Migliorini, 1999); Immunoassay (ed. E. Diamandis and T. Christopoulus, 1997); Molecular Biology Techniques (ed. W.Ream and K. Field, 1999); Kathy Barker, At the Bench (1998), all of which are hereby incorporated by reference.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle. Moreover, the claims filed with this application are intended to be as comprehensive as possible: EVERY novel and nonobvious disclosed invention is intended to be covered, and NO subject matter is being intentionally abandoned, disclaimed, or dedicated.

What is claimed is:

1. A measurement system comprising:
an electromagnetic interface to a fluid medium;
a coating of a binding material on said electromagnetic interface, said binding material containing haptomers which selectively bind to a particular antigen; and
an RF electronics stage which is connected to provide RF energy to said electromagnetic interface and to be pulled by changing dielectric characteristics as haptomers in said binding material bind said antigen from said fluid medium.

2. The system of claim 1, wherein said second electromagnetic interface contains a coating of a binding material not containing said haptomer.

3. The system of claim 1, wherein said fluid medium is a liquid.

4. The system of claim 1, wherein said haptomer is an antibody.

5. The system of claim 1, wherein said binding material is an ion-exchange resin.

6. The system of claim 1, wherein said binding material is an agarose material.

7. A measurement system comprising:
a first electromagnetic interface to a fluid medium;
a coating of a binding material on said first electromagnetic interface, said binding material containing haptomers which selectively bind to a particular antigen;
a second electromagnetic interface to the fluid medium; and
an RF electronics stage which is connected to provide RF energy to said first and/or second electromagnetic interface and to be pulled by changing dielectric characteristics as haptomers in said binding material bind said antigen from said fluid medium.

8. The system of claim 7, wherein said second electromagnetic interface contains a coating of a binding material not containing said haptomer.

9. The system of claim 7, wherein said fluid medium is a liquid.

10. The system of claim 7, wherein said haptomer is an antibody.

11. The system of claim 7, wherein said binding material is an ion-exchange resin.

12. The system of claim 7, wherein said binding material is an agarose material.

13. A characterization method, comprising the actions of:
(a.) providing RF energy to a circuit element which is electromagnetically loaded by a haptomeric material which is in contact with a fluid medium;
(b.) monitoring time-resolved reactive behavior of said circuit element, to thereby derive information about the presence, in said fluid medium, of antigens which bind selectively to said haptomeric material.

14. The method of claim 13, comprising the preceding action of preconditioning said haptomeric material to reduce the fraction of haptomers therein which are bound to their complemenary antigens.

15. A characterization method, comprising the steps of:
(a.) exposing a haptomeric material to a fluid medium; and
(b.) monitoring changes in the dielectric properties of said haptomeric material, to thereby derive a measurement of the concentration, in said fluid medium, of antigens which bind selectively to said haptomeric material.

16. The method of claim 15, comprising the preceding action of preconditioning said haptomeric material to reduce the fraction of haptomers therein which are bound to their complemenary antigens.
